(19) United States
(12) Patent Application Publication
(10) Pub. No.: US 2025/0267899 A1
(43) Pub. Date: Aug. 21, 2025

(54) CHANNEL WITH ANGULAR INDENT

(71) Applicant: INTERNATIONAL BUSINESS MACHINES CORPORATION, ARMONK, NY (US)

(72) Inventors: Pouya Hashemi, Purchase, NY (US); Shogo Mochizuki, Mechanicville, NY (US)

(21) Appl. No.: 18/581,962

(22) Filed: Feb. 20, 2024

(51) Int. Cl. H01L 29/786; H01L 29/06; H01L 29/08; H01L 29/423; H01L 29/66; H01L 29/775

(52) U.S. Cl. CPC H10D 30/6757; H10D 30/014; H10D 30/031; H10D 30/43; H10D 30/6735; H10D 62/121; H10D 62/151; H10D 64/017

(57) ABSTRACT

A transistor includes a channel that has sidewall that consists of an angular indent that is directly connected to the source/drain region without a channel extension region therebetween. For example, the transistor may be a p-type transistor in which the channel may be composed of silicon germanium (SiGe) and may be directly connected to a p-type source/drain region. Unlike some traditional pFETs, there is not a traditional channel extension region (e.g., a Si channel extension region) between the SiGe channel and the p-type source/drain regions. As such, the resistance between the channel and the source/drain is relatively reduced.

### BACKGROUND

The present disclosure relates to fabrication methods and resulting structures for semiconductor devices. More specifically, the present disclosure relates to fabrication methods and resulting semiconductor integrated circuit (IC) devices that include a transistor with one or channels that have respective angular indents in direct contact with a source/drain region.

Some gate all around (GAA) transistors may utilize a cladded channel that may be formed around a thinned nanosheet. In these transistors, a channel extension region typically remains underneath a gate spacer and directly between the cladded channel and a source/drain (S/D) region. The existence of this channel extension region undesirably adds resistance between the S/D region and the cladded channel.

### SUMMARY

In an embodiment of the present disclosure, a transistor is presented. The transistor includes a source/drain region. The transistor further includes a channel that has one or more angular indents. The angular indent(s) is directly in contact with the source/drain region. The transistor further includes a gate structure that is directly in contact with a top surface of the channel and that is directly in contact with a bottom surface of the channel.

In an embodiment of the present disclosure, another transistor is presented. The transistor includes a source/drain region. The transistor further includes a channel region that includes a series of vertically stacked channels each comprising respective angular indents that are in direct contact with the source/drain region. The transistor further includes a gate structure that is directly in contact with a respective top surface and a bottom surface of each of the vertically stacked channels.

In an embodiment of the present disclosure, a method of forming a semiconductor integrated circuit (IC) device is presented. The method includes trimming an active nanolayer that is composed of a first semiconductor material resulting in a portion of the active nanolayer that is trimmed and an end portion of the active nanolayer that is non-trimmed. The method further includes forming a second semiconductor material directly upon the portion of the active nanolayer that is trimmed. The method further includes intermixing the second semiconductor material and the first semiconductor material. The method further includes removing the end portion of the active nanolayer that is non-trimmed resulting in forming an angular indent within the channel.

The above summary is not intended to describe each illustrated embodiment or every implementation or example of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-sectional view of an illustrative semiconductor integrated circuit (IC) device that includes one or more channels that include a respective angular indent, according to embodiments of the disclosure.

FIG. 2 depicts a cross-sectional view of an illustrative channel that includes a respective angular indent, according to embodiments of the disclosure.

FIG. 3 depicts a cross-sectional view of an illustrative source/drain region, according to embodiments of the disclosure.

FIG. 4 depicts a partial top-down view of an illustrative semiconductor integrated circuit (IC) device that is to include one or more channels that include a respective angular indent, according to embodiments of the disclosure.

FIG. 5 through FIG. 21 depict various fabrication cross-sectional views of an illustrative semiconductor integrated circuit (IC) device that includes one or more channels that include a respective angular indent, according to embodiments of the disclosure.

FIG. 22 depicts a method of fabricating a semiconductor integrated circuit (IC) device that includes one or more channels that include a respective angular indent, according to one or more embodiments of the disclosure.

### DETAILED DESCRIPTION

The present disclosure relates to fabrication methods and resulting semiconductor IC devices that include one or more channels that include a respective angular indent. Due to a desire to reduce the resistance between a cladded channel and an S/D region, a transistor is disclosed that includes one or more channels that include a respective angular indent in direct contact with a source/drain region.

The embodiments of the present disclosure recognize the potential benefits of semiconductor IC device fabrication techniques that allow for both a direct connection between the angular indent and the source/drain region and for relatively increased interfacial area between the angular indent and the source/drain region, which may reduce the resistance therebetween.

The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure may be a structure used to control output current (i.e., flow of carriers in the channel) of a semiconducting device through electrical or magnetic fields. A channel may be the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns may be formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode may be electrically insulated from the main semiconductor n-channel or p-channel by a thin layer of insulating material, for example, silicon dioxide or glass, which makes the input resistance of the MOSFET relatively high. The gate voltage controls whether the current path from the source to the drain may be an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET may be related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device may be finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which may be necessary for continuously scaling gate lengths.

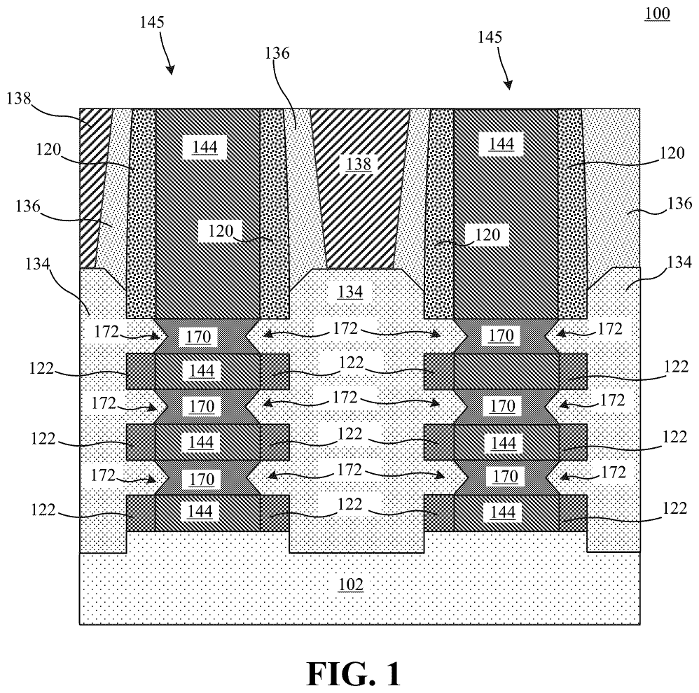

Referring now to FIG. 1, a cross-sectional view of an illustrative semiconductor integrated circuit (IC) device 100 that includes one or more channels 170 that include one or more angular indent(s) is depicted. In implementations, the semiconductor IC device 100 may further include a substrate 102, source/drain region(s) 134, inner spacers 122, replacement gate structure(s) 145, gate spacer(s) 120, an interlayer dielectric (ILD) 136, frontside contact(s) 138, and/or the like. The replacement gate structure(s) 145 may include one or more conductors 144 that may be used to control output current (i.e., flow of carriers through the channels 170).

The channels 170 may be in direct contact with the replacement gate structure(s) 145 and may be further directly between a source and a drain (e.g., source/drain region(s) 134). The channels 170 may become conductive when the transistor is turned on, as dictated, for example, by potential applied to the associated replacement gate structure(s) 145. The source (e.g., a first source/drain region 134) may be a doped semiconductor material in which carriers flow therefrom into a respective angular indent 172 of channels 170. The drain (e.g., a second source/drain region 134) may be a doped semiconductor material in which carriers flow from a respective angular indent 172 of channels 170 thereto.

In embodiments, the channel 170 may be directly connected to the source and to the drain without a channel extension region therebetween. For example, the transistor may be a p-type transistor in which the channel 170 may be composed of silicon germanium (SiGe) and may be directly connected to a p-type source/drain region 134 (e.g., composed of boron doped SiGe). Unlike some traditional pFETs, there is not a traditional channel extension region (e.g., a Si channel extension region) between the SiGe channel 170 and the p-type source/drain regions 134. As such, the resistance between the source and channel 170 and/or the drain and channel 170 is relatively reduced.

Each channel 170 generally includes an angular indent 172 at its interface with the each of the source/drain regions 134. Each angular indent 172 is generally a recessed or inwardly removed region of the channel 170 at its interface with the source/drain regions 134. Each angular indent 172 may include a downward face that angularly faces the backside of the semiconductor IC device 100 and an upward face that angularly faces the frontside of the semiconductor IC device 100. The downward face and an upward face may be orthogonal, may be acutely angled with respect to each other, or may be obtusely angled with respect to each other. The downward face and the upward face may intersect at an angular indent 172 apex which is generally inset within or internal to the channel 170. The angular indent 172 apex may be further inset within or between the respective sidewalls of the replacement gate structure 145 that resultantly form its gate length.

When both source/drain interface walls of the channel 170 include a respective angular indent 172, as depicted, a dimension between the respective angular indent 172 apexes is generally less than a same orientated dimension of the top and/or bottom surface of the channel 170. In other words, the channel 170 is narrower between the angular indents 172 than at the top and/or bottom surfaces. The downward face of the angular indent 172 may be acutely angled from the top surface of the channel 170. Similarly, the upward face of the angular indent 172 may be acutely angled from the bottom surface of the channel 170.

Generally, the angular indents 172 of channel 170 may provide for an increased interfacial area (e.g., relatively to a channel with a substantially vertical sidewall) between the channel 170 and the source/drain regions 134, which may further reduce the resistance therebetween or increase the effectiveness of applied strain from the source/drain region 134 to the channel 170.

In an example, the channel 170 may be composed of SiGe with a relative percentage of Ge between 10% and 80%. In an example, at least a portion of each angular indent 172 may be inset relative to an inner spacer 122 and/or gate spacer 120 there above and/or there below so that the source/drain region 134 does not directly contact the replacement gate structure 145. In some cases, the SiGe channel 170 has a uniform Ge concentration across its interface to the source/drain region 134. In other cases, the SiGe channel 170 has a non-uniform, graded, layered, or the like, Ge concentration, with multiple Ge concentration fractions across its interface to the source/drain region 134. In some instances, the channel 170 may include an internal Si portion, located at a horizontal bisector of the channel 170, in which the SiGe portions are cladded therearound.

The substrate 102 may be utilized as a base structure to fabricate the transistor that includes the one or more channels 170. The inner spacers 122 may adequately electrically isolate the associated source/drain region 134 from the replacement gate structure 145. The gate spacer(s) 120 may also adequately electrically isolate the associated source/drain region 134 from the replacement gate structure 145. The frontside contact(s) 138 may be formed in middle of line (MOL) processing within the ILD 136 and may connect the various transistor features (e.g., replacement gate structure(s) 145, source/drain regions 134, etc.) to a frontside back end of line (BEOL) network (not shown). Further details of these features are described with reference to the fabrication views of the drawings.

In an illustrated example, the semiconductor IC device 100 may include one or more GAA FETs. The GAA FETs provide a relatively small FET footprint by arranging the channel as vertically stacked channels 170. In an illustrated GAA configuration, the GAA FET includes a source region (a first S/D region 134), a drain region (a first S/D region 134), and vertically stacked channels 170 between the source and drain regions. The replacement gate structure 145 is directly connected to the stacked channels 170 and regulates carrier flow through the vertically stacked channels 170 between the S/D regions 134.

For n-type GAA FETs, the channels 170 may be, for example, silicon (Si), relaxed SiGe, or strained Si₁₋ₓGeₓ wrapped around relaxed Si_{1-y}Ge_{y}, where 0≤x≤y≤1. For p-type GAA FETs, the channels 170 can be, for example, SiGe, compressively strained SiGe, strained Si₁₋ₓGeₓ wrapped around relaxed Si_{1-y}Ge_{y}, where 0≤y≤x≤1, or the like, with or without a cladding Si cap with thickness between 1 to 20 Å. Forming channels 170 from SiGe or Si, depending upon the transistor type, may provide for superior channel mobility as well as reduced series resistance, which is beneficial for continuously scaling gate lengths.

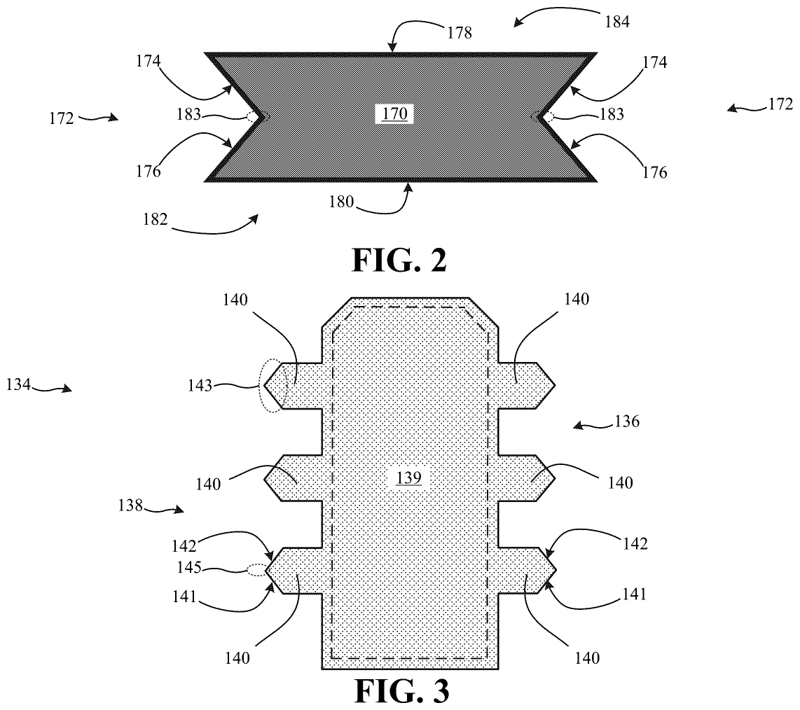

FIG. 2 depicts a cross-sectional view of a channel 170, according to embodiments of the disclosure. Each angular indent 172 of the channel 170 is generally a recessed or inwardly removed region of the channel 170 located at a side or end surface(s) of the channel 170 that directly contacts a respective source/drain region 134. The angular indent 172 may include a downward face 174 that angularly faces the backside of the semiconductor IC device 100 and an upward face 176 that angularly faces the frontside of the semiconductor IC device 100.

The downward face 174 and the upward face 176 may be orthogonal, may be acutely angled with respect to each other, or may be obtusely angled with respect to each other. The downward face 174 may be acutely angled from a top surface 178 of the channel 170. Similarly, the upward face 176 may be acutely angled from a bottom surface 180 of the channel 170. The downward face 174 and the upward face 176 may be generally linear, as depicted. Alternatively, the downward face 174 and the upward face 176 may be generally curved, non-linear, or the like. For example, the downward face 174 and the upward face 176 may be associated with a circular or curved angular indent 172 profile.

The downward face 174 and the upward face 176 may intersect at an angular indent 172 apex 183 which is generally inset within or internal to the channel 170. When both side or end surface(s) of the channel 170 include a respective angular indent 172, as depicted, a horizontal dimension in the plane of the page between the respective angular indent 172 apexes 183 is generally less than a horizontal dimension in the plane of the page of the top surface 178 and/or the bottom surface 180 of the channel 170. The channel 170 may further include a front surface 182 and a rear surface 184. The profile shape of the channel 170 may be the same or similar from the front surface 182 to the rear surface 184.

FIG. 3 depicts a cross-sectional view of an illustrative source/drain region 134, according to embodiments of the disclosure. Source/drain region 134 may be composed of a doped semiconductor material and can be a source region or a drain region depending on subsequent wiring and application of voltages during operation of the applicable transistor. The dopant that is present in the source/drain region 134 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, include, but are not limited to, antimony, arsenic and phosphorous. In one example, the Source/drain region 134 can have a dopant concentration of from 4×10²⁰ atoms/cm³ to 3×10²¹ atoms/cm³. When the semiconductor material of source/drain region 134 is doped with a p-type dopant, the resulting source/drain region 134 are referred to herein as being p-doped and when the semiconductor material is doped with a n-type dopant, the resulting source/drain region 134 are referred to herein as being n-doped.

The source/drain region 134 may include a main body region 139 and one or more teeth regions 140 extending substantially horizontally from respective sidewall(s) of the main body region 139. The sidewall of the main body region 139 may be associated with or coincident with the gate spacer 120 and/or inner spacers 122, depicted in FIG. 1, of the semiconductor IC device 100. As such, at least a portion of the teeth region 140 may be inset within, between, and/or underneath the gate spacer 120 and/or inner spacers 122. For clarity, teeth regions 140 and main body region 139 are an integral source/drain region 134 but are referred to having different element numbers to better describe their respective geometries, or the like.

Each teeth region 140 may include an extension region 143 located at a side or end surface(s) of the teeth region 140 that which directly contacts a respective channel 170. Each extension region 143 may include a downward face 141 that angularly faces the backside of the semiconductor IC device 100 and an upward face 142 that angularly faces the frontside of the semiconductor IC device 100. The extension region 143 may be the portion of the teeth region 140 that is located within or internal to the angular indent 172 of the associated channel 170.

The downward face 141 and the upward face 142 may be orthogonal, may be acutely angled with respect to each other, or may be obtusely angled with respect to each other. The downward face 141 may be obtusely angled from a bottom surface of the teeth region 140. Similarly, the upward face 142 may be obtusely angled from a top surface of the teeth region 140. The downward face 141 and the upward face 142 may be generally linear, as depicted. Alternatively, the downward face 141 and the upward face 142 may be generally curved, non-linear, or the like. For example, the downward face 141 and the upward face 142 may be associated with a circular or curved profile.

The downward face 141 and the upward face 142 may intersect at an apex 145 which is generally the outward most portion of the teeth region 140. The downward face 141 may be juxtaposed against or otherwise coincident with the upward face 176 of the associated channel 170. Similarly, the upward face 142 may be juxtaposed against or otherwise coincident with the downward face 174 of the associated channel 170. The apex 145 of the teeth region 140 may be coincident with the angular indent 172 apex 183.

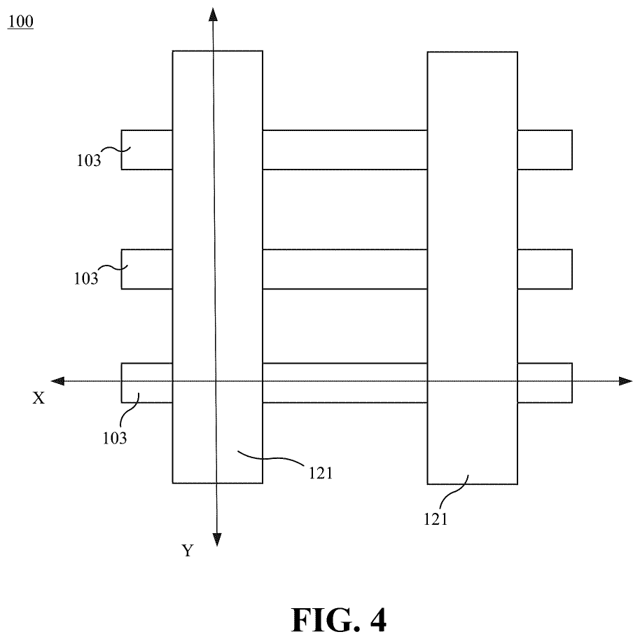

FIG. 4 depicts a partial top-down view of semiconductor IC device 100, according to embodiments of the disclosure. The depicted view defines various cross-sectional planes that are utilized to depict the various fabrication cross-sectional views of semiconductor IC device 100. A cross-sectional plane “X” extends through a nanosheet row 103 and across a sacrificial gate structure(s) 121. A cross-sectional plane “Y” extends through a sacrificial gate structure 121 and across nanosheet rows 103.

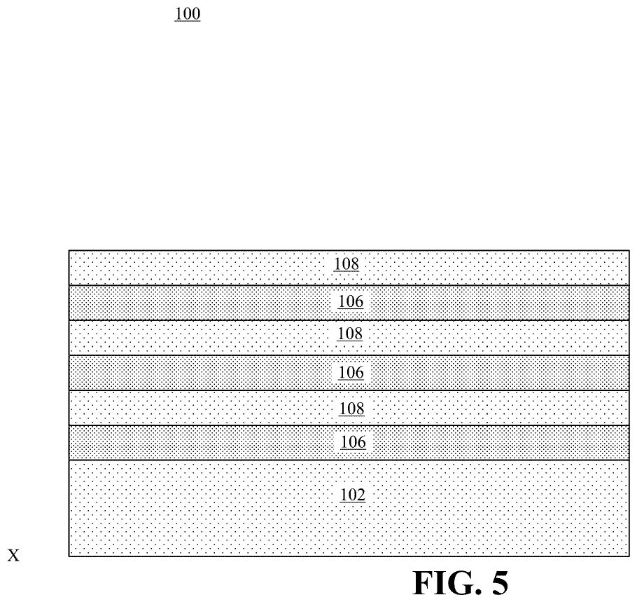

FIG. 5 depicts a cross-sectional view of the semiconductor IC device 100 after initial fabrication operations. In these fabrication stages, nanolayers may be formed upon a substrate structure 102.

The substrate structure 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed.

Nanolayers may be formed upon the substrate structure 102 by forming alternating blanket layers of sacrificial nanolayers 106 and active nanolayers 108. In certain examples, the first one of the sacrificial nanolayers 106 is initially formed directly on an upper surface of the substrate structure 102. In other examples, certain layers may be formed between the upper surface of the substrate structure 102 and the first one of the sacrificial nanolayers 106. In an example, each sacrificial nanolayers 106 is composed of silicon-germanium (e.g., SiGe, where the Ge ranges from about 25-40%). Next, a blanket layer of the active nanolayer 108 may be formed on an upper surface of the first one of the sacrificial nanolayers 106. In an example, the active nanolayer 108 is composed of silicon. Several additional blanket layers of the sacrificial nanolayers 106 and active nanolayers 108 are alternately formed. In the illustrated semiconductor IC device 100, there are a total of three sacrificial nanolayers 106 and three active nanolayers 108. However, it should be appreciated that any suitable number of alternating layers may be formed.

Although it is specifically contemplated that the blanket sacrificial nanolayers 106 can be formed from SiGe and that the blanket active nanolayers 108 can be formed from Si, it should be understood that any appropriate materials can be used instead, as long as the two semiconductor materials have etch selectivity with respect to one another.

The alternating blanket nanolayers can be deposited by any appropriate mechanism. The alternating blanket nanolayers can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In certain embodiments, the blanket sacrificial nanolayers 106 have a vertical thickness ranging, for example, from approximately 3 nm to approximately 20 nm. In certain embodiments, the sacrificial nanolayers 106 and active nanolayers 108 have a vertical thickness ranging, for example, from approximately 3 nm to approximately 10 nm. Although the range of 3-20 nm is cited as an example range of thickness of the sacrificial nanolayers 106 and active nanolayers 108, other thickness of these nanolayers may be used. In certain examples, certain of the sacrificial nanolayers 106 and active nanolayers 108 may have different thicknesses relative to one another. For example, multiple epitaxial growth processes can be performed to form the alternating the sacrificial nanolayers 106 and active nanolayers 108.

In certain embodiments, it may be desirable to have a small vertical spacing (VSP) between adjacent active nanolayers 108 to reduce the parasitic capacitance and to improve circuit speed. For example, the VSP (the distance between adjacent active nanolayers 108) may range from 5 nm to 15 nm. However, the VSP must be of a sufficient value to accommodate the conductive replacement gate that will be formed in the spaces created by later removal of respective portions of the sacrificial nanolayers 106.

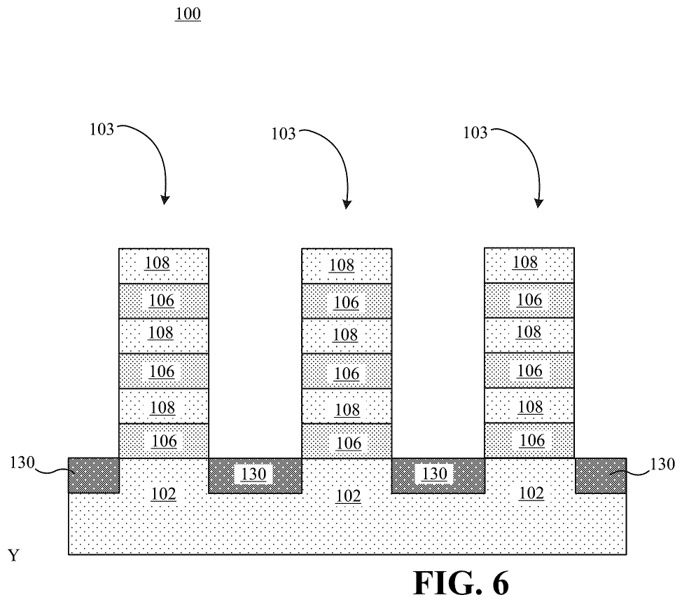

FIG. 6 depicts a cross-sectional view of the semiconductor IC device 100 after fabrication operations, in accordance with embodiments of the present disclosure. In the depicted fabrication stages, the nanolayers are patterned into nanolayer rows 103, and shallow trench isolation (STI) regions 130 may be formed.

To form one or more nanolayer rows 103, a mask layer (not shown) may be formed on the uppermost nanolayer. The mask layer may be comprised of any suitable material(s) known to one of skill in the art. The mask layer may be patterned and used to perform the nanolayer row 103 patterning process. In the nanolayer row 103 patterning process, any suitable material removal process (e.g., reactive ion etching or RIE) may be used to remove portions of the alternating nanolayers down to the level of the substrate structure 102, down to the insulator layer within the substrate structure, or the like. Following the nanolayer row 103 patterning process, one or more nanolayer rows 103 may be formed. As depicted, within each nanolayer row 103 there are alternating sacrificial nanolayers 106 and active nanolayers 108 formed from the associated blanket nanolayers, respectively. Subsequently, the mask layer may be removed.

The removal of undesired portion(s) of the alternating nanolayers may further remove undesired portions of substrate structure 102 that are adjacent to respective footprints of nanolayer rows 103 to form STI region openings. The etch may be timed or otherwise controlled to stop the removal of the substrate structure 102 such that the depth or bottom of the one or more STI region openings has a predetermined or desired dimension. Alternatively, the etch may utilize the etch stop layer (not shown) that is internal to the substrate structure 102 to effectively stop the etch to form the depth or bottom of the one or more STI region openings.

A STI region 130 may be formed upon the substrate structure 102 below and adjacent to the nanolayer rows 103 within the STI region openings. For example, one or more STI regions 130 may be formed by depositing dielectric isolation material within the STI region openings adjacent to the one or more nanolayer rows 103. A top surface of the one or more STI regions 130 may be coplanar with a top surface of substrate structure 102. The STI region(s) 130 may be formed by depositing dielectric material upon the substrate structure 102 to a thickness such that the top surface of the dielectric material is coplanar with the top surface of the substrate structure 102. The one or more STI regions 130 may have a volume that sufficiently electrically isolates components or features of neighboring transistors, or the like.

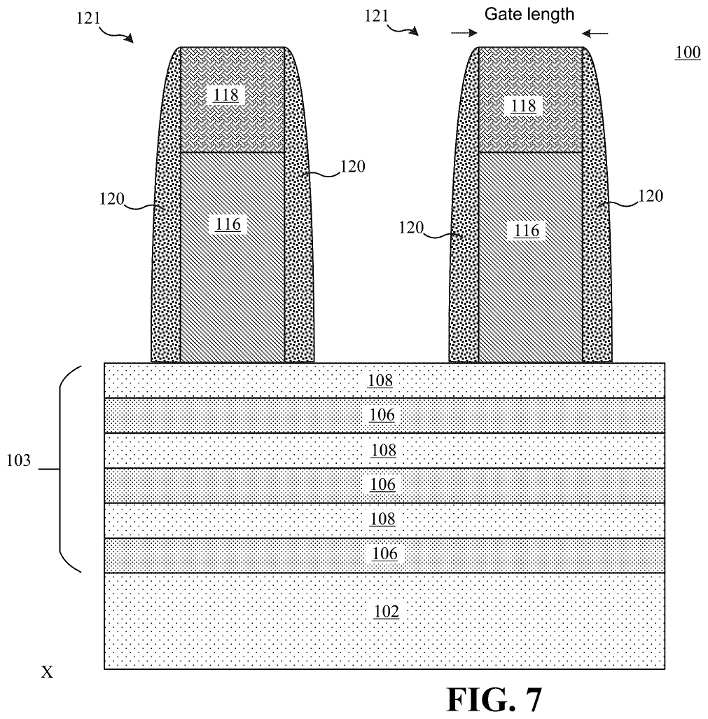

FIG. 7 depicts a cross-sectional view of the semiconductor IC device 100 after fabrication operations, in accordance with embodiments of the present disclosure. In the depicted fabrication stages, sacrificial gate structures 121 and gate spacers 120 may be formed.

The one or more sacrificial gate structures 121 may be formed upon the STI regions 130 (not shown in the depicted cross-section) and upon and around the one or more nanolayer rows 103. The one or more sacrificial gate structures 121 may include a sacrificial gate liner (not shown), a sacrificial gate 116, and a sacrificial gate cap 118.

The sacrificial gate structures 121 may be formed by initially depositing the sacrificial gate liner layer (e.g., a dielectric, oxide, or the like) upon the one or more STI regions and upon and around the one or more nanolayer rows 103. The sacrificial gate structures 121 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 103. The sacrificial gate structures 121 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 121 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 116, and the sacrificial gate cap 118, respectively, of each of the one or more sacrificial gate structures 121.

One or more sacrificial gate structures 121 can be formed on targeted regions or areas of semiconductor IC device 100 to define the length of one or more GAA FETs, length of the top surface 178 (depicted in FIG. 2) and/or bottom surface 180 (depicted in FIG. 2) of the channel(s) 170 between a respective source and drain, and to provide sacrificial material for yielding targeted GAA FET structure(s) in subsequent processing. According to an example, each sacrificial gate structure 121 can have a height of between approximately 50 nm and approximately 200 nm, and a gate length of between approximately 10 nm and approximately 200 nm.

One or more gate spacers 120 may be respectively formed upon the one or more STI regions 130 (not shown in FIG. 7), upon and around the one or more nanolayer rows 103, and upon and around the sacrificial gate structure(s) 121. In one example, gate spacers 120 may be formed of a dielectric material(s), such as such as silicon nitride, SiBCN, SiNC, SiN, SiCO, SiNOC, a combination thereof, or the like.

The one or more gate spacers 120 may be formed by a deposition of a blanket gate spacer dielectric material. Excess, undesired, and/or exposed blanket gate spacer dielectric material may be subsequently removed by a substrative removal technique, such as an etch. For example, a directional etch may remove exposed horizontal portion(s) of the blanket gate spacer dielectric material while also leaving vertical portion(s) of the blanket gate spacer dielectric material, upon the sidewall perimeter of each of the one or more sacrificial gate structures 121 intact.

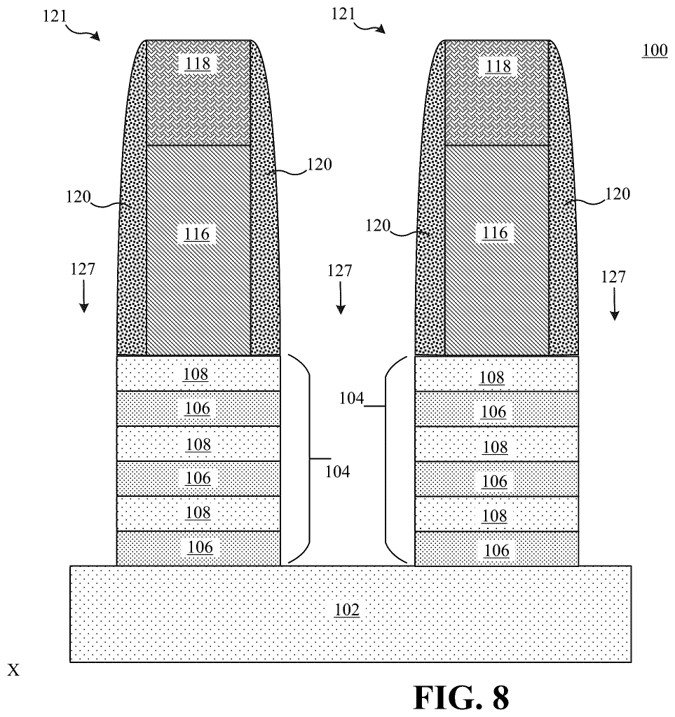

FIG. 8 depicts a cross-sectional view of the semiconductor IC device 100 after fabrication operations, in accordance with embodiments of the present disclosure. In the depicted fabrication stages, source/drain (S/D) recesses 127 may be formed within the one or more nanolayer rows 103 between gate spacers 120 that are associated with neighboring sacrificial gate structures 121. In other words, a single nanolayer row 103 may be separated into multiple nanolayer columns 104, each located underneath a sacrificial gate structure 121, by the formation of one or more S/D recesses 127.

The one or more S/D recesses 127 may be formed between adjacent sacrificial gate structures 121 by removing respective portions of the sacrificial nanolayers 106 and active nanolayers 108 that are between gate spacers 120 of adjacent or neighboring sacrificial gate structures 121. The one or more S/D recesses 127 may be formed to a depth to stop at the substrate structure 102. In this manner, a respective nanolayer row 103 is separated. In the separation, respective portions of the sacrificial nanolayers 106 and the active nanolayers 108 that are located below the gate spacers 120 and below the sacrificial gate structures 121 may be retained. The undesired portions of the nanolayers may be removed by etching or other subtractive removal techniques. The top surface of the substrate structure 102 or the STI region(s) 130 may be used as an etch stop or other etch parameters may be controlled to stop the material removal at the substrate structure 102. The retained one or more portions of one or more nanolayer rows 103 may be such portions of the alternating nanolayers that were protected generally below and/or internal to respective sacrificial gate structures 121 and/or by the associated gate spacers 120, herein referred to as nanolayer columns 104. As such, as is depicted, respective sidewalls or end surfaces of the retained sacrificial nanolayers 106 and the active nanolayers 108 may be coplanar with respective outer sidewalls of the associated gate spacers 120.

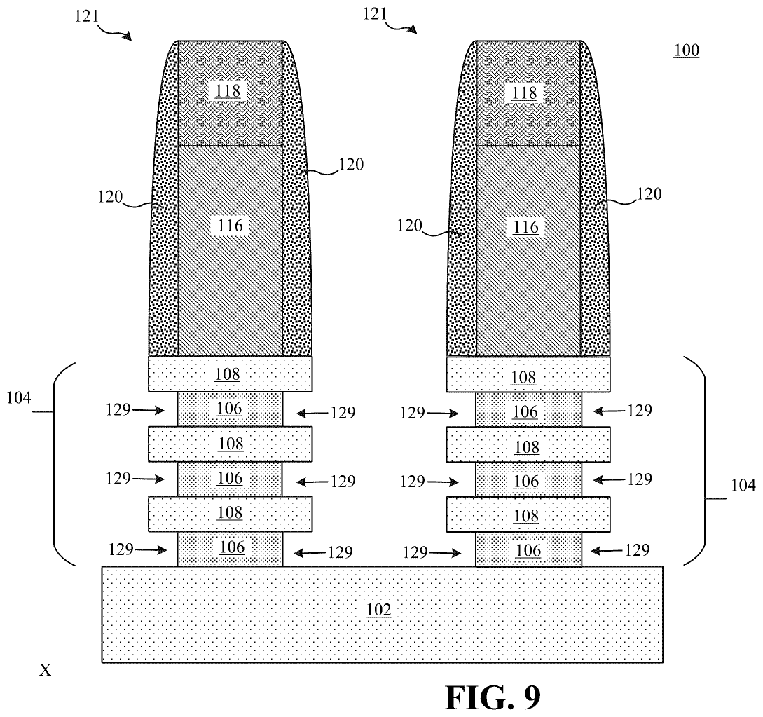

FIG. 9 depicts a cross-sectional view of the semiconductor IC device 100 after fabrication operations, in accordance with embodiments of the present disclosure. In the depicted fabrication stages, indents 129 may be formed by removing respective portions of sacrificial nanolayers 106 that are not covered by the sacrificial gate 116.

Indents 129 may be formed by a reactive ion etch (RIE) process and a wet etch process, which can remove portions of the sacrificial nanolayers 106 not covered by the sacrificial gate 116 and/or that are underneath the gate spacer(s) 120. The horizontal depth of the indents 129 may be chosen to set a length for the replacement gate structure formed in place of the sacrificial gate structure 121. When the sacrificial nanolayers 106 are composed of SiGe, the directional RIE can use a boron-based chemistry or a chlorine-based chemistry, for example, which recesses or removes the exposed end portions of sacrificial nanolayers 106 (e.g., those portions of sacrificial nanolayers 106 generally below spacer 120, etc.) selective to the Si active nanolayers 108. In alternative implementations, when sacrificial nanolayers 106 are not SiGe and when active nanolayers 108 are not Si, the directional etch of the sacrificial nanolayers 106 may generally be selective to the active nanolayers 108, gate spacers 120, and/or substrate structure 102.

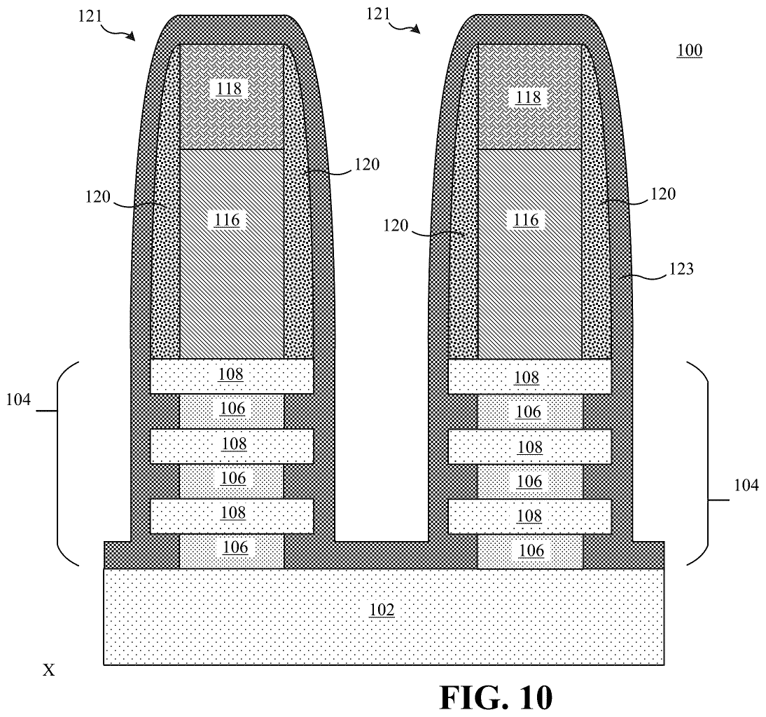

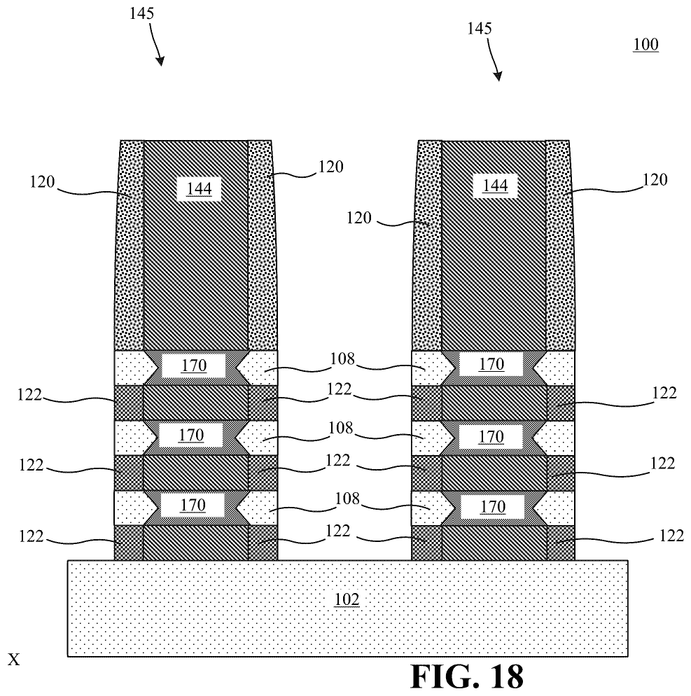

FIG. 10 depicts a cross-sectional view of the semiconductor IC device 100 after fabrication operations, in accordance with embodiments of the present disclosure. In the depicted fabrication stages, a liner layer 123 may be formed within the one or more indents 129, upon the gate spacer(s) 120, upon the active nanolayers 108, upon the sacrificial nanolayers 106, upon the substrate structure 102, upon the STI regions 130, etc. In implementation(s), the liner layer 123 may protect the source/drain area (s), in which S/D regions are to be formed, and may in subsequent processes may be used to form inner spacer(s) 122, depicted in FIG. 18.

The liner layer 123 can be formed by ALD or CVD or any other suitable deposition technique that deposits material upon the semiconductor IC device 100, such as a blanket layer deposition technique. In some examples, the liner layer 123 is composed of a low-κ dielectric material (a material with a lower dielectric constant relative to SiO₂), SiN, SiO, SiBCN, SiOCN, SiCO, etc. or any other suitable dielectric material.

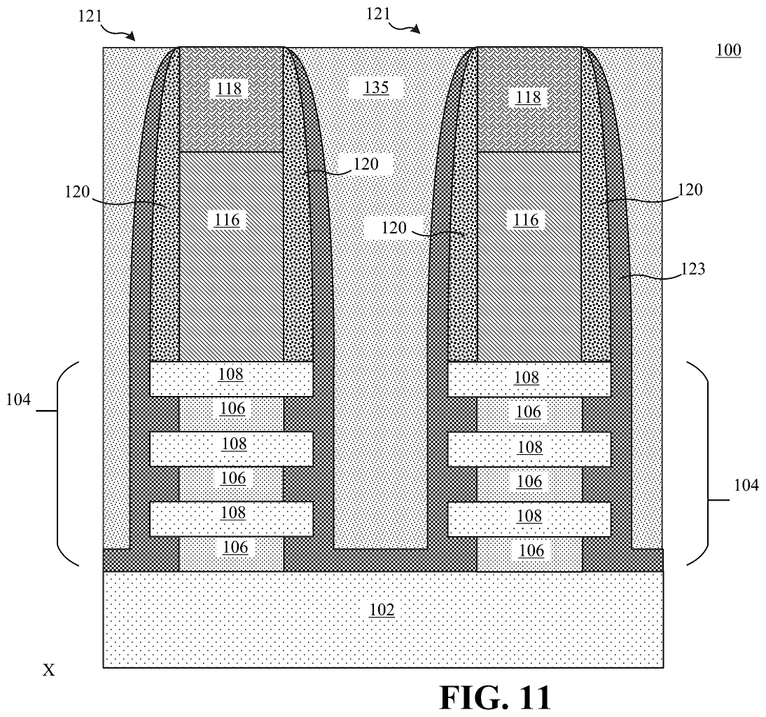

FIG. 11 depicts a cross-sectional view of the semiconductor IC device 100 after fabrication operations, in accordance with embodiments of the present disclosure. In the depicted fabrication stages, a sacrificial interlayer dielectric (ILD) 135 may be formed upon the liner layer 123.

The sacrificial ILD 135 may be formed by depositing a dielectric material upon the liner layer 123. The sacrificial ILD 135 can be any suitable material, such as, for example, porous silicates, carbon doped oxides, silicon dioxides, silicon nitrides, silicon oxynitrides, or other dielectric materials. Any known manner of forming the sacrificial ILD 135 can be utilized. The sacrificial ILD 135 can be formed using, for example, CVD, PECVD, ALD, flowable CVD, spin-on dielectrics, or PVD. In an example, the sacrificial ILD 135 may be formed to a thickness above the top surface of the sacrificial gate structures 121.

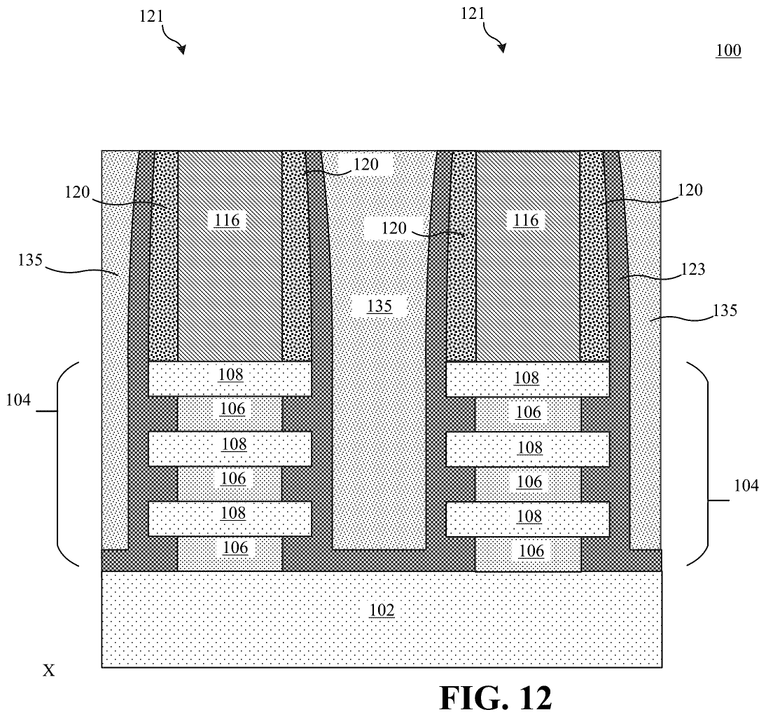

FIG. 12 depicts a cross-sectional view of the semiconductor IC device 100 after fabrication operations, in accordance with embodiments of the present disclosure. In the depicted fabrication stages, the sacrificial gate(s) 116 of the sacrificial gate structure(s) 121 may be exposed.

The sacrificial gate(s) 116 of the sacrificial gate structure(s) 121 may be exposed by a planarization process, such as a chemical mechanical polish (CMP) that removes the sacrificial gate cap 118 (shown in FIG. 11), partially removes the excess sacrificial ILD 135, partially removes the liner layer 123, and partially remove the gate spacers 120. The planarization may also partially remove some of the sacrificial gate 116 or may at least expose the sacrificial gate 116 of the sacrificial gate structures 121. The CMP may create a planar or horizontal top surface for the semiconductor IC device 100. In other words, the respective top surfaces of sacrificial ILD 135, liner layer 123, gate spacers 120, and sacrificial gates 116 may be substantially horizontal and/or substantially coplanar.

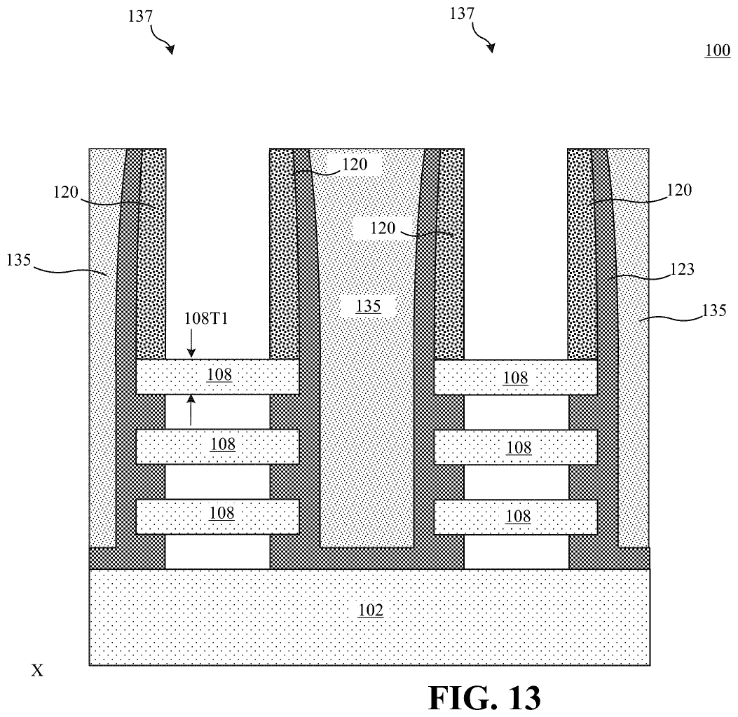

FIG. 13 depicts a cross-sectional view of the semiconductor IC device 100 after fabrication operations, in accordance with embodiments of the present disclosure. In the depicted fabrication stages, the sacrificial gate structures 121 (shown in FIG. 12) are removed. Further, in the depicted fabrication stages, the active nanolayers 108 are released by removing the sacrificial nanolayers 106 (shown in FIG. 12).

The sacrificial gate structure 121 may be removed by initially removing the sacrificial gate 116 and sacrificial gate oxide by a removal technique, such as one or more series of etches. For example, such removal may be accomplished by a wet chemical etching process in which one or more chemical etchants are used to remove the sacrificial gate 116 (shown in FIG. 12) and sacrificial gate oxide of the sacrificial gate structures 121 (shown in FIG. 12). Appropriate etchants may be used that remove the sacrificial gate 116 and/or sacrificial gate oxide selective to the active nanolayers 108, liner layer 123, gate spacers 120, or the like.

The sacrificial nanolayers 106 (shown in FIG. 12) may be removed by a removal technique, such as one or more series of etches. For example, the etching can include a wet chemical etching process in which one or more chemical etchants are used to remove the sacrificial nanolayers 106 (shown in FIG. 12). Appropriate etchants may be used that remove the sacrificial nanolayers 106 selective to the active nanolayers 108, liner layer 123, gate spacers 120, or the like. After the removal of sacrificial nanolayers 106, a gate opening 137 is created by the removal of a respective sacrificial gate structure 121 and releasing of the associated active nanolayers 108. For clarity, after the active nanolayers 108 are released have a vertical thickness 108T1.

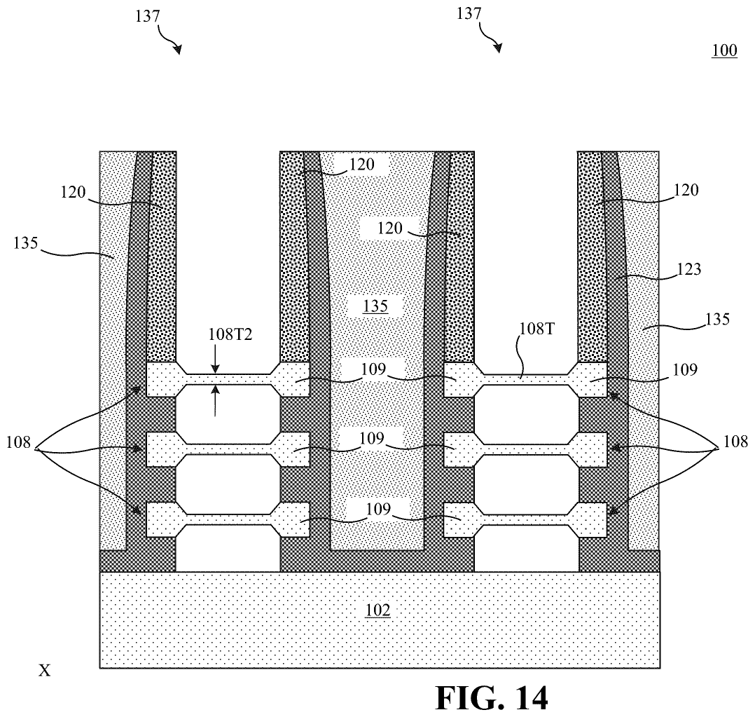

FIG. 14 depicts a cross-sectional view of the semiconductor IC device 100 after fabrication operations, in accordance with embodiments of the present disclosure. In the depicted fabrication stages, the active nanolayers 108 may be thinned or trimmed through gate opening 137 to reduce the thickness of (or trim) at least a portion of the active nanolayers 108 exposed within the gate opening 137, which may be referred herein as trimmed active nanolayers 108T. Non-trimmed portions 109 remain positioned at least within the liner layer 123.

The thinning or trimming process may be accomplished by an etch or other material removal technique that reduces the thickness of the trimmed active nanolayers 108T from their initial vertical thickness 108T1, depicted in FIG. 13, to a reduced final vertical thickness 108T2, i.e., the trimmed active nanolayers 108T have a reduced thickness as compared to the first and second non-trimmed initial thickness portions 108T1 of the active nanolayers 108. The amount of trimming performed on the trimmed active nanolayers 108T may vary depending upon the application. In one illustrative example, the trimming process may be performed such that the final thickness 108T2 is about 25-50% less than the initial thickness 108T1 of the active nanolayers 108. The above stated range (about 25-50%) should not be considered to be restrictive as to the inventions disclosed herein as the relative decrease (in terms of percentage) between the initial thickness 108T1 and the final thickness 108T2 may vary depending upon the exact process flow selected and material removal technique selected. For example, the active nanolayers 108 could be formed with a relatively thin initial thickness 108T1 and then be trimmed by about 5-10% to achieve the targeted final thickness 108T2. Conversely, the active nanolayers 108 could be formed with a very thick initial thickness 108T1 and then be trimmed by about 80-90% to meet the targeted final thickness 108T2.

Reducing the size or thickness of the active nanolayers 108 has the effect of creating relatively larger spaces between the trimmed active nanolayers 108T. Also note that, in some applications, the final trimmed (reduced-thickness) active nanolayers 108 may also comprise simplistically depicted facets (e.g., crystalline (111) surface facets that form upward face 142 and downward face 141) that serve as a transition region between the reduced-thickness 108T2 portion of trimmed active nanolayers 108T and the non-trimmed portions 109 of the active nanolayers 108.

In one illustrative example, the active nanolayers 108 may be trimmed (or reduced in size) by performing a vapor phase HCl etching process, a Frontier process (by Applied Materials) using H₂ and NH₃ or an inter-layer (IL) process that is a well-controlled oxidation process combined with a well-controlled HF etching process, or any other process permitting well-controlled removal of the material of the active nanolayers 108.

Note that, since the sacrificial gate structure 121 was removed before the trimming process is performed, the trimming or size-reduction of the active nanolayers 108 occurs in both the gate width (into and out of the page) and gate length direction (as depicted) of the device semiconductor IC device 100.

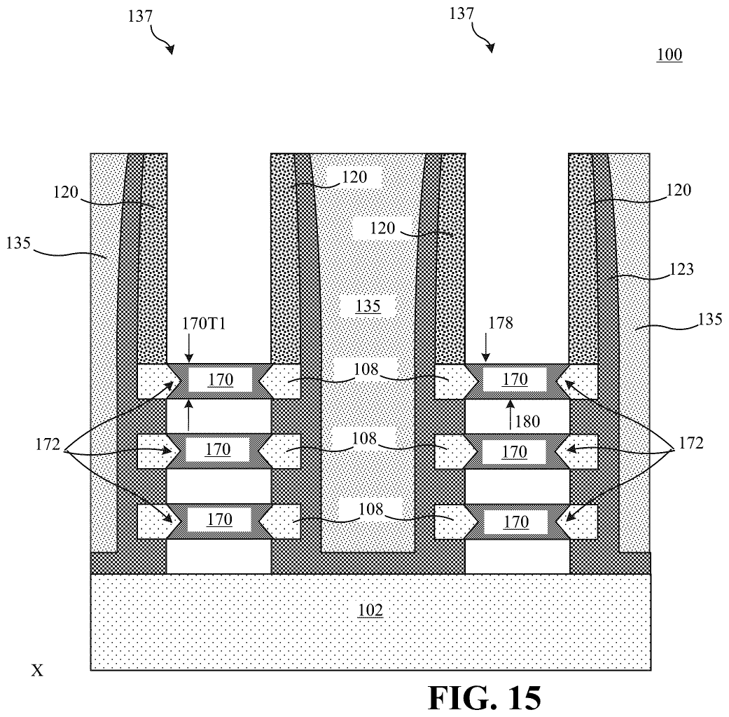

FIG. 15 depicts a cross-sectional view of the semiconductor IC device 100 after fabrication operations, in accordance with embodiments of the present disclosure. In the depicted fabrication stages, channels 170 may be formed.

In one example, as depicted, channels 170 may be formed by epitaxially growing semiconductor material (e.g., SiGe, or the like) from the trimmed active nanolayers 108T, as depicted in FIG. 14, followed by a thermal intermixing stage to create a homogeneous material channel 170 (i.e., the thermal intermixing may effectively drive the newly grown epitaxy material into the trimmed active nanolayers 108T). In other examples, the thermal intermixing stage may be absent, and the epitaxially growing semiconductor material may be present upon a trimmed active nanolayer 108T core.

The channels 170 may be accomplished by epitaxial growth from the trimmed active nanolayers 108T, as depicted in FIG. 14, and/or the crystalline (111) surface facets between the trimmed active nanolayers 108T and the non-trimmed nanolayer portions 109, as depicted in FIG. 14. The epitaxial growing increases the thickness of the channels 170 to 170T1 from the reduced final vertical thickness 108T2. The thickness 170T1 may be substantially the same as the thickness of 108T1, as depicted. As such, the top surface 178 and bottom surface 180 may be substantially coplanar with the respective top surface or bottom surface of the non-trimmed active nanolayer(s) 108 associated therewith. Regrowth of the size or thickness of channels has the effect of creating relatively smaller spaces between channels relative to the increased space between the trimmed active nanolayers 108T.

For clarity, the angular indent 172 of the channels 170 may be at least partially the result of the epitaxial growth of the semiconductor material of the channels 170 against the facets (e.g., crystalline (111) surface facets that form upward face 142 and downward face 141, as depicted in FIG. 2) that serve as a transition region between the reduced-thickness 108T2 portion of trimmed active nanolayers 108T and the non-trimmed portions 109 of the active nanolayers 108, as depicted in FIG. 14.

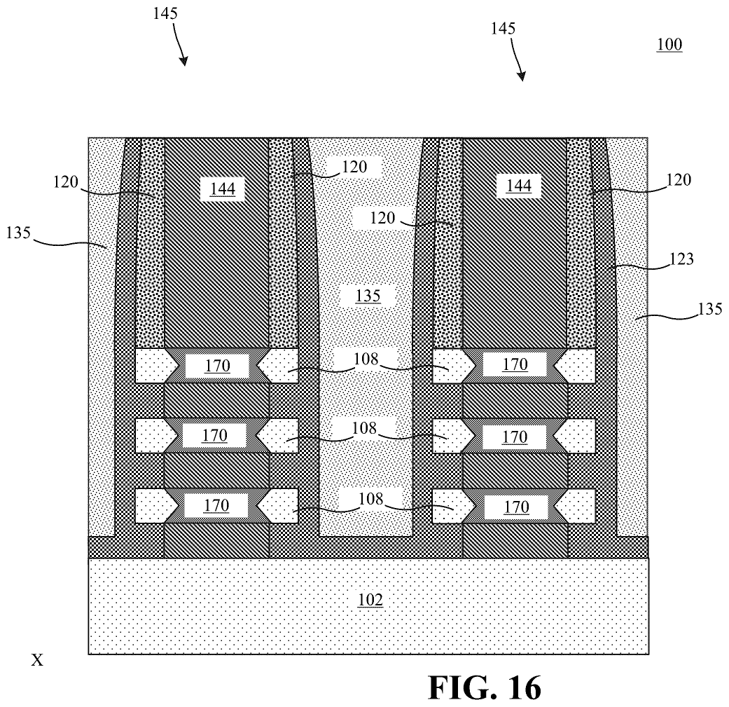

FIG. 16 depicts a cross-sectional view of the semiconductor IC device 100 after fabrication operations, in accordance with embodiments of the present disclosure. In the depicted fabrication stages, replacement gate structures 145 may be formed around the channels 170 within respective gate openings 137.

Replacement gate structure(s) 145 may be formed by initially forming an interfacial layer (not shown) on the interior surfaces of the gate spacer 120, the interior surfaces of the liner layer 123, and the interior surfaces of the channels 170. The replacement gate structure(s) 145 may be further formed by forming a high-κ layer (not shown) over the formed the interfacial layer. The high-κ layer can be deposited by any suitable techniques, such as ALD, CVD, metal-organic CVD (MOCVD), physical vapor deposition (PVD), thermal oxidation, combinations thereof, or other suitable techniques. The high-κ layer may be composed of a high-κ dielectric material which is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-κ layer can include a single layer or multiple layers.

Replacement gate structure(s) 145 may be further formed by depositing a work function (WF) gate (not shown) upon the high-κ layer. The WF gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-κ layer separates the WF gate from the channels 170. Other metals that may be desired to further fine tune the effective work function (eWF) and/or to achieve a desired resistance value associated with current flow through the gate in the direction parallel to the plane of the nanolayer channel.

The one or more replacement gate structures 145 may be further formed by depositing a conductive fill gate 144 upon the WF gate. The conductive fill gate 144 can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 145 formation, the top surface of the semiconductor IC device 100 may be planarized by a planarization technique such as a CMP, mechanical grinding process, or the like. After the planarization technique, respective top surfaces of the sacrificial ILD 135, gate spacers 120, replacement gate structure(s) 145, liner layer 123, etc. may be substantially horizontal and/or may be substantially coplanar.

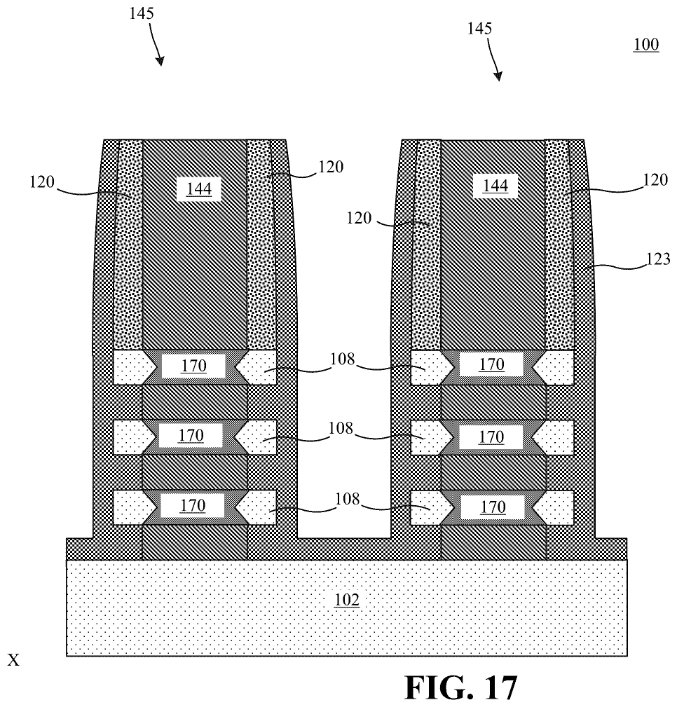

FIG. 17 depicts a cross-sectional view of the semiconductor IC device 100 after fabrication operations, in accordance with embodiments of the present disclosure. In the depicted fabrication stages, sacrificial ILD 135 may be removed. The sacrificial ILD 135 may be removed by an etch that removes the material of the sacrificial ILD 135 selective to the material of the liner layer 123. In some cases, the liner layer 123 may be utilized as an etch stop for the etch that selectively removes the sacrificial ILD 135. In the sacrificial ILD 135 removal process, the replacement gate structure(s) 145, the gate spacers 120, and the liner layer 123 may be retained. In examples, the sacrificial ILD 135 may be removed may be removed to generally expose the liner layer 123.

FIG. 18 depicts a cross-sectional view of the semiconductor IC device 100 after fabrication operations, in accordance with embodiments of the present disclosure. In the depicted fabrication stages, inner spacers 122 may be formed from the liner layer 123 (shown in FIG. 17). For example, an isotropic etch process is performed to create inner spacers 122 with respective outer vertical surfaces that align with outer vertical surfaces of the active nanolayers 108 and/or of the gate spacers 120. In examples, the partial removal of the liner layer 123 (shown in FIG. 17) generally exposes the substrate structure 102 and/or the STI region(s) 130 while the inner spacers 122 are retained.

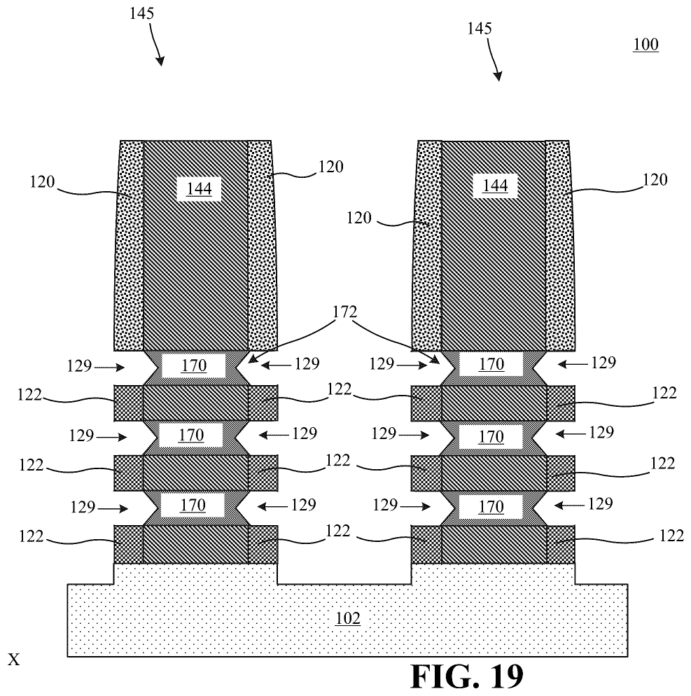

FIG. 19 depicts a cross-sectional view of the semiconductor IC device 100 after fabrication operations, in accordance with embodiments of the present disclosure. In the depicted fabrication stages, indents 129 may be formed by removing the remaining portions of active nanolayers 108 (shown in FIG. 18) that are underneath a respective gate spacer 120 while retaining the associated channel 170, to form the respective angular indent 172 of the associated channel 170.

Indents 129 may be formed by a selective etch process, which can remove portions of the active nanolayers 108 (shown in FIG. 18) that are underneath the gate spacer 120 and adjacent to the channel 170. In an implementation, the indents 129 may form the angular indent 172 of the channel 170 which may advantageously increase the interfacial surface area of the of the channel 170 which is to contact the to-be formed S/D region(s).

The etch of the active nanolayers 108 (shown in FIG. 18) to form indents 129 may generally be selective to the respective materials of inner spacers 122, gate spacers 120, channel 170, or the like. For clarity, the term “active nanolayers” is utilized herein with reference to active nanolayers 108, even though such active nanolayers 108 are sacrificial in the depicted region of the semiconductor IC device 100. In non-depicted regions of the semiconductor IC device 100, the active nanolayers 108 may not be sacrificial, may be retained, and may serve as the active channels to respective FETs therein. For example, in nFET regions there may be nFETs in which the active nanolayers 108 are the channels therein and in pFET regions the active nanolayers 108 are sacrificial for the channels 170, as described and depicted.

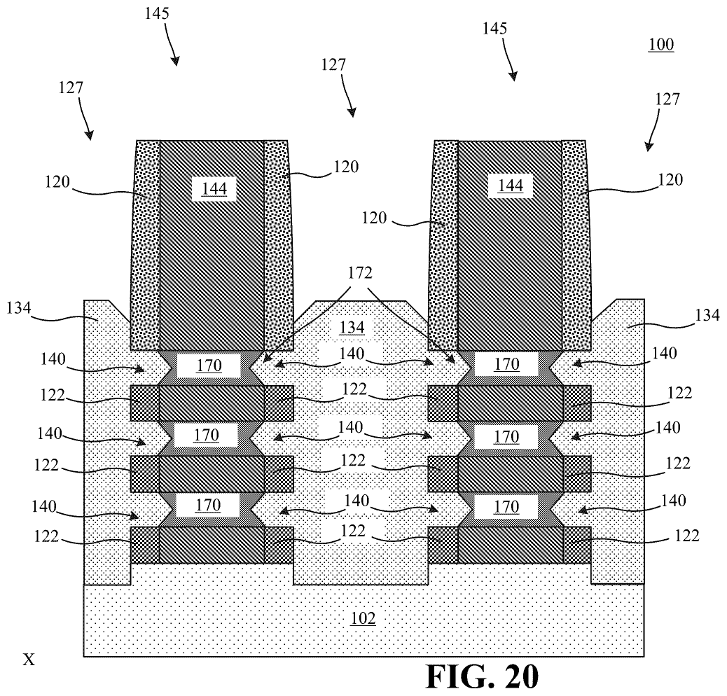

FIG. 20 depicts a cross-sectional view of the semiconductor IC device 100 after fabrication operations, in accordance with embodiments of the present disclosure. In the depicted fabrication stages, the substrate structure 102 may be partially recessed and one or more source/drain (S/D) regions 134 may be formed.

The substrate structure 102 may be partially recessed by for example an etch. In a particular example, the one or more S/D one or more S/D recesses 127 may be deepened within the substrate structure 102.

Each S/D region 134 forms either a source or a drain, respectively, of respective one or more GAA FETs and is connected to respective angular indent(s) 172 of the channel(s) 170. Each of the S/D region 134 is composed of a semiconductor material and a dopant. As used herein, a “source/drain” region can be a source region or a drain region depending on subsequent wiring and application of voltages during operation of the transistor. The semiconductor material that provides each of the S/D region 134 is composed of one of the semiconductor materials mentioned above for the semiconductor structure 102. The semiconductor material that provides the S/D region 134 can be compositionally the same, or compositionally different from that used to form the active nanolayers 108. The dopant that is present in the S/D region 134 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the S/D region 134 can have a dopant concentration of from 1×10²¹ atoms/cm³ to 3×10²¹ atoms/cm³. In a particular example, where the channels 170 are composed of SiGe, the S/D regions 134 may be p-type S/D regions 134.

S/D region(s) 134 may be epitaxially grown or formed. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material may be formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

The S/D region(s) 134 may be formed by epitaxially growing a source/drain region within the recess or opening between neighboring nanolayer FETs. In some examples, S/D region(s) 134 may be formed by in-situ doped epitaxial growth. In some embodiments, the S/D region(s) 134 epitaxial growth may overgrow above the upper surface of the semiconductor IC device 100.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors.

In certain implementations, the S/D region(s) 134 may be overgrown and then partially recessed such that an upper portion of the S/D region(s) 134 are removed. For example, the upper portion of the one or more S/D region(s) 134 may be etched or otherwise removed. The etch may be timed or otherwise controlled to stop the removal of S/D region(s) 134 such that the top surface of S/D region(s) 134 is above the upper surface of the topmost channel 170.

For clarity, during the formation of the S/D region(s) 134, S/D epitaxy material may grow within indents 129 and may resultantly form a respective teeth region 140 within each indent 129. As such, each teeth region 140 of the S/D region 134 directly contacts, is juxtaposed against, or otherwise is directly touching the associated angular indents 172 of the channel 170.

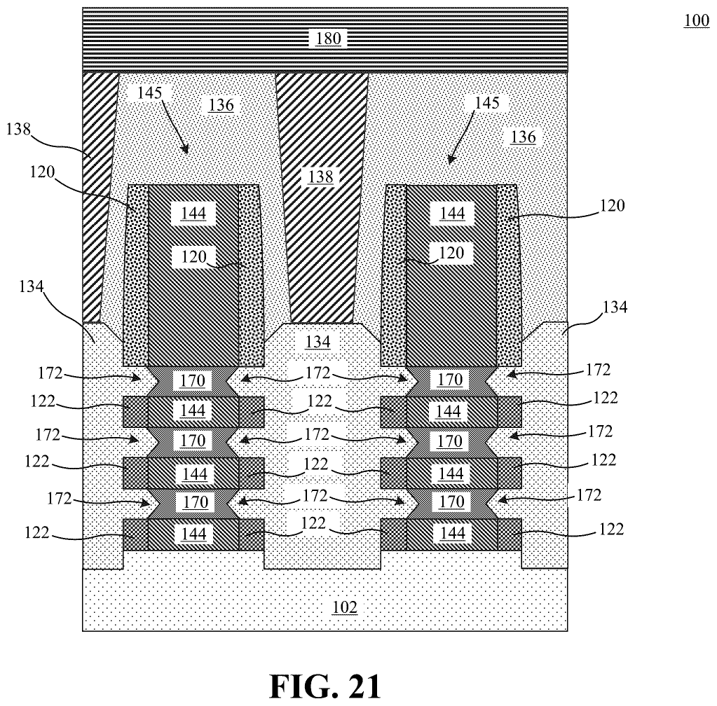

FIG. 21 depicts a cross-sectional view of the semiconductor IC device 100 after fabrication operations, in accordance with embodiments of the present disclosure. In the depicted fabrication stages, interlayer dielectric (ILD) 136 may be formed upon the one or more source/drain (S/D) regions 134 and upon at least the sidewalls of the replacement gate structures 145 and may be further formed upon the STI region(s) 130, as depicted in FIG. 6. Further, in the depicted fabrication stages, one or more frontside contacts 138 may be formed and a frontside front end of line (FEOL) network 180 may be formed.

The ILD 136 may be formed by depositing a blanket dielectric material upon S/D region(s) 134 and upon at least the sidewalls of the replacement gate structures 145 and may be further formed upon the STI region(s) 130. The ILD 136 can be any suitable material, such as, for example, porous silicates, carbon doped oxides, silicon dioxides, silicon nitrides, silicon oxynitrides, or other dielectric materials. Any known manner of forming the ILD 136 can be utilized. The ILD 136 can be formed using, for example, CVD, PECVD, ALD, flowable CVD, spin-on dielectrics, or PVD.

In an example, the ILD 136 may be formed to a thickness above the top surface of the replacement gate structures 145. Subsequently, a planarization process, such as a CMP, may occur. The CMP may create a planar or horizontal frontside surface for the semiconductor IC device 100.

The illustrated semiconductor IC device 100 may be further fabricated by forming frontside contacts 138 within the ILD 136. The frontside contacts 138 may be formed by patterning respective frontside contact openings within frontside contact ILD 136 from the frontside (i.e., from above the semiconductor IC device 100, as depicted, downward to respective structures thereof). The frontside contacts 138 may be in direct or indirect physical and electrical contact and/or may physically meld with respective material(s) of one or more regions of the semiconductor IC device 100. For example, an illustrated frontside contact 138 is in direct contact with S/D region 134. A different frontside contact 138 may be in direct contact with a particular replacement gate structure 145 in a different plane into or out of the page.

The frontside contacts 138 may be formed by initially forming frontside contact opening(s). The frontside contact opening(s) may be formed by the same or shared lithography and etch process(es) or by sequential lithography and etch processes. In such process(es), a mask may be applied and patterned. An opening in the patterned mask may expose the portion of the underlying ILD 136 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention. Generally, the frontside contact openings expose at least a portion of the underlying semiconductor IC device 100 structure with which the associated frontside contact 138 is to make direct contact.

The frontside contact(s) 138 may be further formed by depositing conductive material such as metal into the respective frontside contact opening(s). In an example, frontside contact(s) 138 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. Subsequently, the respective top surfaces of frontside contact(s) 138 and the ILD 136 may be substantially horizontal and/or substantially coplanar. In embodiments, the frontside contact(s) 138 are fabricated in middle-of-line (MOL) fabrication operations and may be illustrations of MOL frontside contacts.

In the semiconductor IC device fabrication industry, there are three sections referred to in a typical semiconductor IC device build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there is one BEOL level on the frontside of the semiconductor IC device 100. However, an additional backside BEOL level may further be formed on the opposing backside of the semiconductor IC device 100, each on opposites sides of the semiconductor IC device 100.

In the depicted example, the frontside BEOL network 180 is formed over the ILD 136 and upon the frontside contacts 138. Respective wires within the frontside BEOL network 180 may be electrically connected to the one or more S/D regions 134, to the one or more replacement gate structure(s) 145, or the like, by a respective frontside contact 138. For example, respective wire(s) within the frontside BEOL network 180 may be electrically connected to appropriate S/D regions 134 by a frontside contact 138, another and different group of respective wire(s) within the frontside BEOL network 180 may be electrically connected to appropriate replacement gate structures 145, etc.

In different implementations, the frontside contacts 138 may take the form of BEOL interconnects. In these implementations, the respective wires within the frontside BEOL network 180 may be electrically connected to the S/D regions 134, replacement gate structure(s) 145, or the like, by a lowest BEOL interconnect, such as a vertical interconnect access (VIA), that is within the frontside BEOL network 180.

The frontside BEOL network 180 may be located directly on the frontside surface of the MOL structure (e.g., ILD 136, frontside contact(s) 138, etc.). The frontside BEOL network 180 can include one or more interconnect dielectric material layers (including one of the dielectric materials mentioned above for the ILD 136) and contains metal wires (the metal wires can be composed of any electrically conductive metal or electrically conductive metal alloy) embedded therein. In some embodiments, the frontside metal wires within the frontside BEOL network 180 are composed of Cu. The frontside BEOL network 180 can include “x” numbers of frontside metal levels, wherein “x” is an integer starting from 1. The frontside BEOL network 180 may further contain conductive pads that are connected to one or more of the metal wires and may be used to connect the semiconductor IC device 100 to an external and/or higher-level structure, such as a chip carrier, motherboard, or the like.

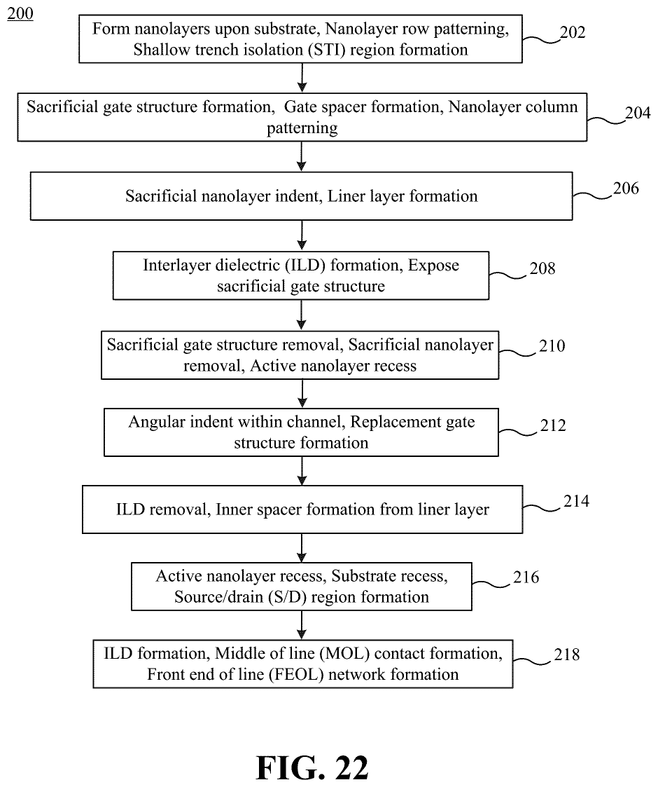

FIG. 22 depicts a flow diagram illustrating method 200 to fabricate a semiconductor IC device, such as semiconductor IC device 100. The depicted fabrication operations of method 200 are illustrated and described above with reference to one or more of FIG. 5 through FIG. 21 of the drawings, which describe the fabrication of semiconductor IC device 100, though the fabrication operations described in method 200 may be used to fabricate other types of semiconductor IC devices. The method 200 depicted herein is illustrative. There can be many variations to the diagram or operations described therein without departing from the spirit of the embodiments. For instance, the operations can be performed in a differing order, or operations can be added, deleted, or modified.

At block 202, method 200 may begin with forming nanolayers upon a substrate, patterning the nanolayers into one or more nanolayer rows, and forming STI regions within the substrate adjacent to the nanolayer rows. For example, method 200 may include forming alternating series of sacrificial nanolayers 106 and active nanolayers 108 upon a substrate structure 102. Further, method 200 may include patterning the nanolayers to form one or more nanolayer rows 103 and with forming STI regions 130 therebetween. For example, predetermined portions of the nanolayers may be removed and a well within the substrate structure 102 may be formed. The portions of the nanolayers that remain may effectively form the one or more nanolayer rows 103 and respective STI regions 130 may be formed within the substrate well between the nanolayer rows 103.

At block 204, method 200 may further continue with forming one or more sacrificial gate structure(s), with forming one or more gate spacers upon the one or more sacrificial gate structure(s), and with nanolayer column patterning. For example, method 200 may include forming one or more sacrificial gate structures 121 upon the substrate structure 102, upon the STI regions 130, and upon and around the nanolayer rows 103. Further, method 300 may include forming one or more gate spacer(s) 120 upon the substrate structure 102 and/or upon the STI regions 130 and upon the sidewall(s) of the sacrificial gate structures 121. For example, the gate spacer(s) 120 may be formed upon the substrate structure 102 or upon the STI regions 130, may be formed upon and around nanolayer rows 103 and may be formed upon and around the one or more sacrificial gate structure(s) 121, respectively. Method 200 may further continue with recessing the nanolayer stacks 103 to form nanolayer columns 104, For example, one or more S/D recesses 127 may be formed within the nanolayer stacks 103 respectively between gate spacers 120 associated with neighboring sacrificial gate structures 121.

At block 206, method 200 may further continue with indenting the sacrificial nanolayers within the nanolayer columns and with forming a respective inner spacer layer. For example, an indent 129 may be formed within respective sacrificial nanolayers 106 within nanolayer columns 104 and a liner layer 123 may be formed upon the sacrificial gate structure(s) 121, upon the gate spacer 120, upon the nanolayer columns 104 and within the indent 129, upon the substrate structure 102, and/or upon the STI regions 130.

At block 208, method 300 may continue with forming a sacrificial ILD and with exposing the sacrificial gate structure(s). For example, sacrificial ILD 135 is formed and recessed to expose the top surface of the sacrificial gate structure(s) 121.

At block 210, method 300 may continue with removing the one or more sacrificial gate structure(s), with removing the sacrificial nanolayers (i.e., the active nanolayers may be released), and with recessing the active nanolayers to form trimmed active nanolayers. For example, the sacrificial gate structure(s) 121 may be removed, the sacrificial nanolayers 106 may be removed thereby releasing the active nanolayers 108 adjacent thereto, and the active nanolayers 108 may be trimmed to form trimmed active nanolayers 108T.

At block 212, method 200 may continue with forming channel(s) and with forming a replacement gate structure. For example, channel(s) 170 may be formed by epitaxially growing a channel material from the trimmed active nanolayers 108T and subjecting the channel structures to a thermal intermix process. Further, replacement gate structure(s) 145 may be formed around the channels 170.

At block 214, method 200 may continue with removing the sacrificial ILD and with forming inner spacers from the inner spacer layer. For example, the sacrificial ILD 135 may be removed, and excess liner layer 123 material may be removed leaving inner spacer(s) 122 between active nanolayers 108.

At block 216, the active nanolayers are removed, the substrate structure may be partially recessed, and S/D regions may be formed. For example, the substrate structure 102 may be partially recessed between adjacent replacement gate structures 145. Next, the S/D regions 134 may be epitaxially grown from the substrate structure 102. During the formation of the S/D region(s) 134, S/D epitaxy material may grow within indents 129 and may resultantly form a respective teeth region 140 within each indent 129. As such, each teeth region 140 of the S/D region 134 directly contacts, is juxtaposed against, or otherwise is directly touching the associated angular indents 172 of the channel 170.

At block 218, method 200 may continue with forming an ILD, with middle of line (MOL) contact formation, and with frontside back end of line (BEOL) network formation. For example, method 200 may include forming ILD 136 upon the replacement gate structure(s) 145, upon the S/D regions 134, upon the substrate structure 102, and upon the STI region(s) 130. Subsequently, respective frontside contacts 138 may be formed upon respective S/D regions 134, upon respective replacement gate structures 145. Further, method 200 may include forming the frontside BEOL network 180 upon the ILD 136 and upon the frontside contacts 138. In some implementations, method 200 may also include subsequent fabrication stages to, for example, fabricate an IC chip, an end product, or the like.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A transistor comprising:
a source/drain region;
a channel comprising a sidewall consisting of an angular indent that is directly in contact with the source/drain region; and
a gate structure that is directly in contact with a top surface of the channel and that is directly in contact with a bottom surface of the channel.

2. The transistor of claim 1, wherein the channel is composed of silicon germanium (SiGe) the source/drain region is a p-type source/drain region.

3. The transistor of claim 1, wherein the sidewall having the angular indent is an inwardly recessed region of the channel at an interface between the source/drain region and the channel.

4. The transistor of claim 3, wherein in the angular indent comprises:
a downward linear face that angularly faces a backside of the semiconductor IC device; and
an upward linear face that angularly faces a frontside of the semiconductor IC device.

5. The transistor of claim 4, wherein the downward face and the upward face intersect at an angular indent apex that is located inset within the channel.

6. The transistor of claim 5, wherein the angular indent apex is further inset between respective sidewalls of the gate structure.

7. The transistor of claim 4, wherein the downward face is acutely angled from the top surface of the channel and wherein the upward face is acutely angled from the bottom surface of the channel.

8. The transistor of claim 1, wherein the source/drain region comprises a main body region and a teeth region that extends from a side of the main body region.

9. The transistor of claim 8, further comprising a gate spacer directly upon a sidewall of the gate structure and an inner spacer directly upon the sidewall of the gate structure, and wherein the teeth region is between the gate spacer and the inner spacer.

10. The transistor of claim 9, wherein the teeth region directly contacts the angular indent of the channel.

11. The transistor of claim 10, wherein the top surface of the channel directly contacts the gate spacer and wherein the bottom surface of the channel directly contacts the inner spacer.

12. The transistor of claim 11, wherein a top surface of the teeth region directly contacts the gate spacer and wherein a bottom surface of the teeth region directly contacts the inner spacer.

13. A transistor comprising:
a source/drain region;
a channel region comprising a series of vertically stacked channels each comprising a respective sidewall consisting of an angular indent that is directly in contact with the source/drain region; and
a gate structure that is directly in contact with a respective top surface and a bottom surface of each of the vertically stacked channels.

14. The transistor of claim 13, wherein the source/drain region comprises a main body region and a plurality of teeth regions that extend from a side of the main body region.

15. The transistor of claim 14, wherein each teeth region of the plurality of teeth regions directly contacts the angular indent of a respective channel of the series of vertically stacked channels.

16. The transistor of claim 15, wherein each angular indent is an inwardly recessed region of the respective channel of the series of vertically stacked channels.

17. The transistor of claim 15, wherein each angular indent comprises:
a downward linear face that angularly faces a backside of the semiconductor IC device; and
an upward linear face that angularly faces a frontside of the semiconductor IC device.

18. The transistor of claim 17, wherein the downward face and the upward face intersect at an angular indent apex that is located inset within the respective channel of the series of vertically stacked channels.

19. The transistor of claim 18, wherein the angular indent apex is further inset between respective sidewalls of the gate structure.

20. A method of forming a semiconductor integrated circuit (IC) device comprising:
trimming an active nanolayer composed of a first semiconductor material to result in a portion of the active nanolayer that is trimmed and an end portion of the active nanolayer that is non-trimmed;
forming a second semiconductor material directly upon the portion of the active nanolayer that is trimmed;
intermixing the second semiconductor material and the first semiconductor material; and
removing the end portion of the active nanolayer that is non-trimmed, resulting in forming a channel.
